(19) United States
(12) Patent Application Publication
(10) Pub. No.: US 2020/0209752 A1
(43) Pub. Date: Jul. 2, 2020

(54) METHOD FOR DOUBLE-SIDED PATTERNING AND METHOD FOR MANUFACTURING TOUCH PANEL

(71) Applicants: Interface Technology (ChengDu) Co., Ltd., Sichuan (CN); Interface Optoelectronics (ShenZhen) Co., Ltd., Guangdong (CN); General Interface Solution Limited, Miaoli County (TW)

(72) Inventors: Han-Lung TSAI, Guangdong (CN); Ping-Yang CHEN, Guangdong (CN); Chun-Ming CHEN, Guangdong (CN)

(21) Appl. No.: 16/382,224

(22) Filed: Apr. 12, 2019

(30) Foreign Application Priority Data
Dec. 28, 2018 (CN) 201811623090.4

(51) Int. Cl. G03F 7/09; G03F 7/00; G06F 3/045; G03F 7/38; G03F 7/20

(52) U.S. Cl. CPC G03F 7/094; G03F 7/0035; G03F 7/2002; G03F 7/38; G06F 3/045

(57) ABSTRACT

A method for double-sided patterning includes the steps below. A transparent laminate is provided. The transparent laminate has a first surface and a second surface opposite thereto. A patterned first photoresist layer is formed on the first surface and a patterned second photoresist layer is formed on the second surface. A transparent layer is formed covering the patterned first photoresist layer. The transparent layer is patterned by using the patterned second photoresist layer as a mask.

### CROSS-REFERENCE TO RELATED APPLICATION

This application claims priority to China Application Serial Number 201811623090.4, filed Dec. 28, 2018, which is herein incorporated by reference in its entirety.

### BACKGROUND

### Field of Invention

The present invention relates to a method of double-sided patterning and a method of manufacturing a touch panel.

### Description of Related Art

Currently, touch panels have been widely applied in display devices of various electronic products to aid users in their use of these electronic products. For touch panels, indium tin oxide (ITO) is usually adopted for forming a transparent conductive electrode, such that the electrodes of the touch area are not easily perceived by the human eye. The touch panel includes a first electrode extending in a first direction and a second electrode extending in a second direction, in which the first electrode is insulated and overlap with the second electrode.

In a touch panel with a single-layer conductive layer (SITO) structure, the first electrode and the second electrode are disposed in the same layer but electrically insulated from each other by an insulating layer at the intersection. The second electrode is located on both sides of the first electrode, and they may be electrically connected through a via in the insulating layer. When establishing an electrical connection by providing metal bridges and an insulating layer with vias, it is common and necessary to perform two or more lithographic processes so as to establish an electrical connection between the second electrodes. However, multiple alignment exposure processes tend to result in high cumulative tolerances or alignment offsets, thereby causing a poor electrical connection between the second electrodes, resulting in low production yield of touch panel.

### SUMMARY

One aspect of the present invention offers a method of double-sided patterning. The method comprises the following steps. A transparent laminate having a first surface and a second surface opposite thereto is provided. A patterned first photoresist layer is formed on the first surface, and a patterned second photoresist layer is formed on the second surface. A transparent layer covering the patterned first photoresist layer is formed. The transparent layer is patterned by using the patterned second photoresist layer as a mask.

Another aspect of the present invention offers a method of manufacturing a touch panel. The method comprises the following steps. A transparent substrate having a first surface and a second surface opposite thereto is provided. A transparent sensing layer is formed on the first surface. A patterned first photoresist layer is formed on the transparent sensing layer, and a patterned second photoresist layer is formed on the second surface. By using the patterned first photoresist layer as a mask, the transparent sensing layer is patterned to form a patterned transparent sensing layer. A third photoresist layer covering the patterned transparent sensing layer is formed. By using the patterned second photoresist layer as a mask, the third photoresist layer is patterned. The patterned third photoresist layer has a plurality of openings exposing a portion of the patterned transparent sensing layer. A patterned conductive bridge is formed in the openings.

### BRIEF DESCRIPTION OF THE DRAWINGS

FIG. 1 is a flow chart of a double-sided patterning method according to an embodiment of the present invention.

FIG. 2 to FIG. 7 are schematic cross-sectional views of various process stages in the double-sided patterning method according to an embodiment of the present invention.

FIG. 8 is a flow chart of a method of manufacturing a touch panel according to another embodiment of the present invention.

FIG. 9 is a partially enlarged view of the touch panel manufactured.

FIG. 10 to FIG. 15 are schematic cross-sectional views of the process stages along line A-A′ of FIG. 9.

FIG. 16 is a flow chart of a method of manufacturing a touch panel according to still another embodiment of the present invention.

FIG. 17 to FIG. 23 are schematic cross-sectional views of various process stages in the method of manufacturing the touch panel of the present invention, and the cross-sectional positions thereof are the same as those in FIG. 10 to FIG. 15.

### DETAILED DESCRIPTION

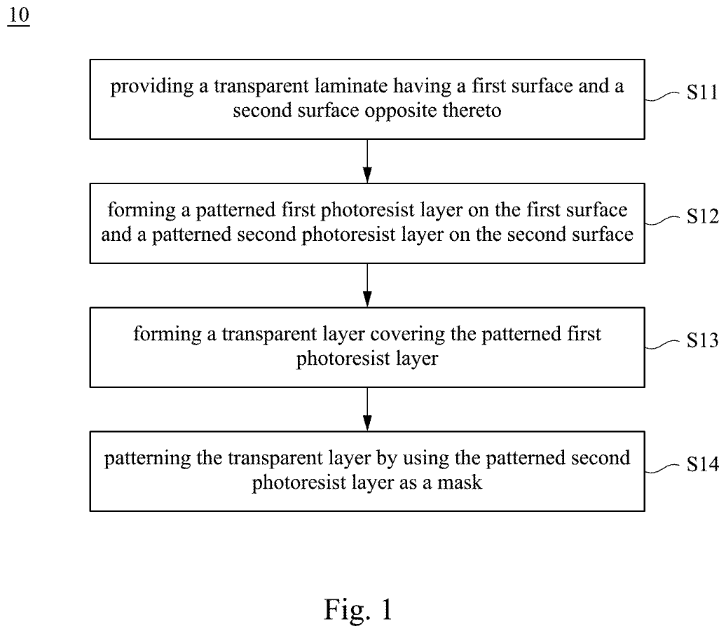

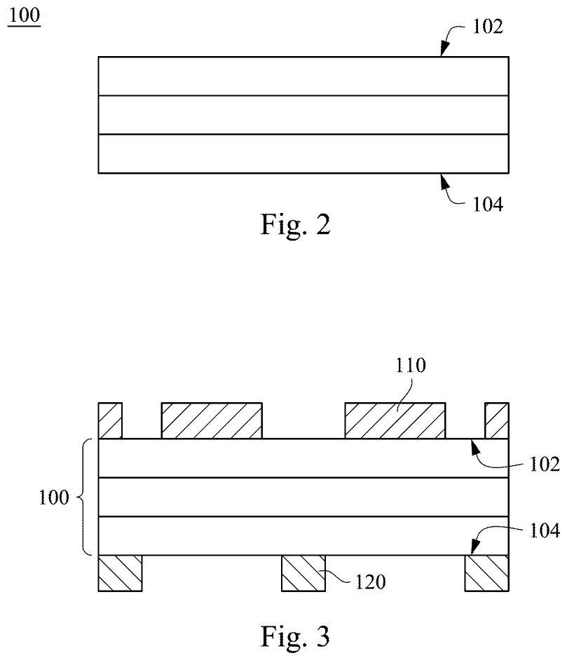

FIG. 1 is a flow chart of a double-sided patterning method according to an embodiment of the present invention. FIG. 2 to FIG. 6 are schematic cross-sectional views of various process stages in the method of the double-sided patterning process according to an embodiment of the present invention. As shown in FIG. 1, a method 10 including step S11, step S12, step S13, and step S14 is provided.

At step S11, a transparent laminate 100 is provided, as shown in FIG. 2. The transparent laminate 100 has a first surface 102 and a second surface 104 opposite thereto. In various embodiments, as shown in FIG. 2, the transparent laminate 100 may have but not limited to three layers. In an embodiment, the transparent laminate 100 can be any suitable transparent material.

At step S12, a patterned first photoresist layer 110 is formed on the first surface 102, while a patterned second photoresist layer 120 is formed the second surface 104, as shown in FIG. 3. In an embodiment, a first photoresist layer is formed on the first surface 102, while a second photoresist layer is formed on the second surface 104. By using the first predetermined mask pattern and the second predetermined mask pattern, the first photoresist layer and the second photoresist layer are respectively exposed and developed.

In an embodiment, the step of patterning the first photoresist layer and the step of patterning the second photoresist layer may be performed simultaneously or individually. In some embodiments, the patterned first photoresist layer 110 and the patterned second photoresist layer 120 each comprises a negative photoresist material. In various embodiments, after performing step S12, the first photoresist layer 110 after patterning and the second photoresist layer 120 after patterning are treated with a curing process, such as ultraviolet light irradiation or baking, or other suitable curing processes.

The higher the optical density of the material is, the better its light masking property will be. The optical density is the logarithmic ratio between the incident light intensity and the transmitted light intensity of a transmissive material. In an embodiment, the patterned second photoresist layer 120 has an optical density (OD) greater than or equal to 3 (for example, 3.05, 3.1, 3.15, 3.2, 3.25, 3.3, 3.35, 3.4, 3.45, or 3.5). Alternatively, the patterned second photoresist 120 needs to contain an opaque material.

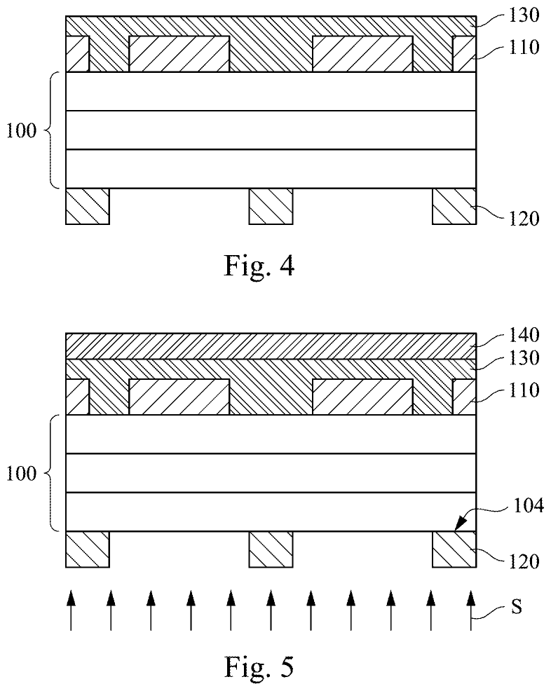

At step S13, a transparent layer 130 is formed covering the patterned first photoresist layer 110, as shown in FIG. 4. In some embodiments, the transparent layer 130 may comprise any suitable transparent material.

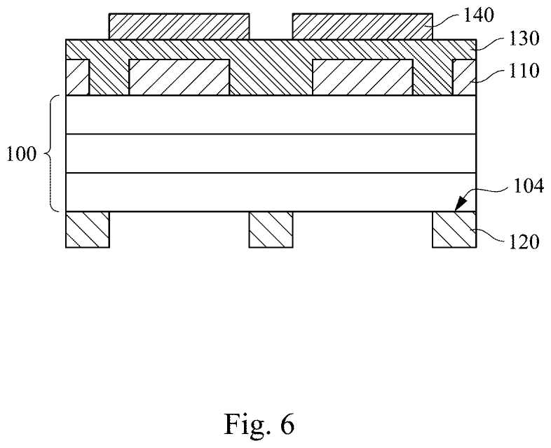

At step S14, the transparent layer 130 is patterned by using the patterned second photoresist layer 120 as a mask. As shown in FIG. 5, a third photoresist 140 is firstly formed on the transparent layer 130. In an embodiment, the third photoresist 140 comprises a negative photoresist material. Since the patterned second photoresist layer 120 is located under the second surface 104 of the transparent laminate 100, the exposure light source “S” may be disposed under the patterned second photoresist layer 120. As shown in FIG. 6, by using the patterned second photoresist layer 120 as a mask, a lithographic process is performed on the third photoresist 140.

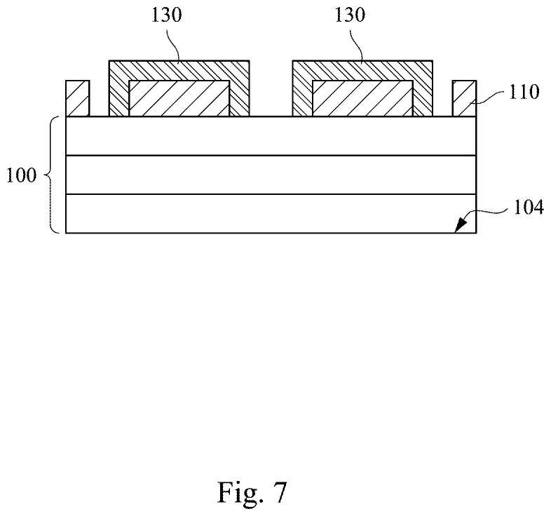

As shown in FIG. 7, the transparent layer 130 is etched according to the pattern of the third photoresist 140 after patterning, and then the third photoresist 140 and the patterned second photoresist layer 120 are removed to accomplish step S14. Since the patterned second photoresist layer 120 has been accomplished in step S12, there is no need for an additional mask or realignment in step S14. Therefore, the cumulative alignment error among multiple lithographic processes can be reduced.

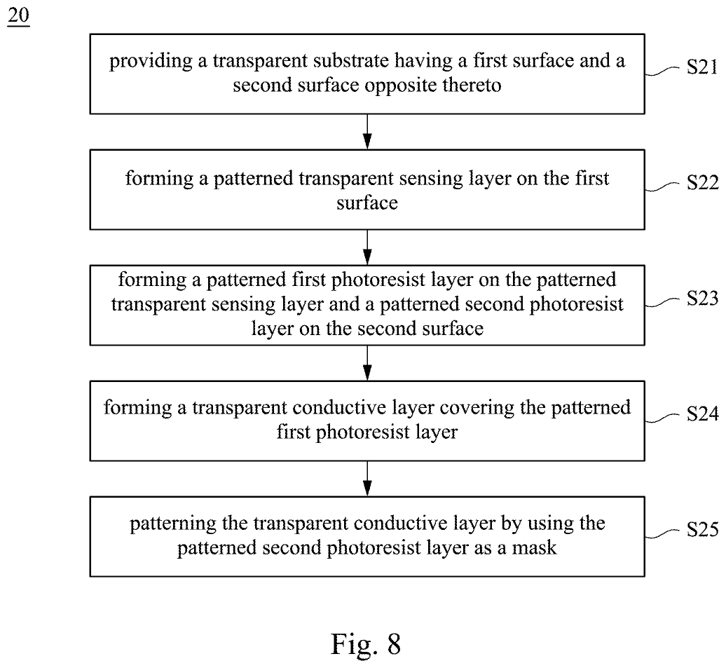

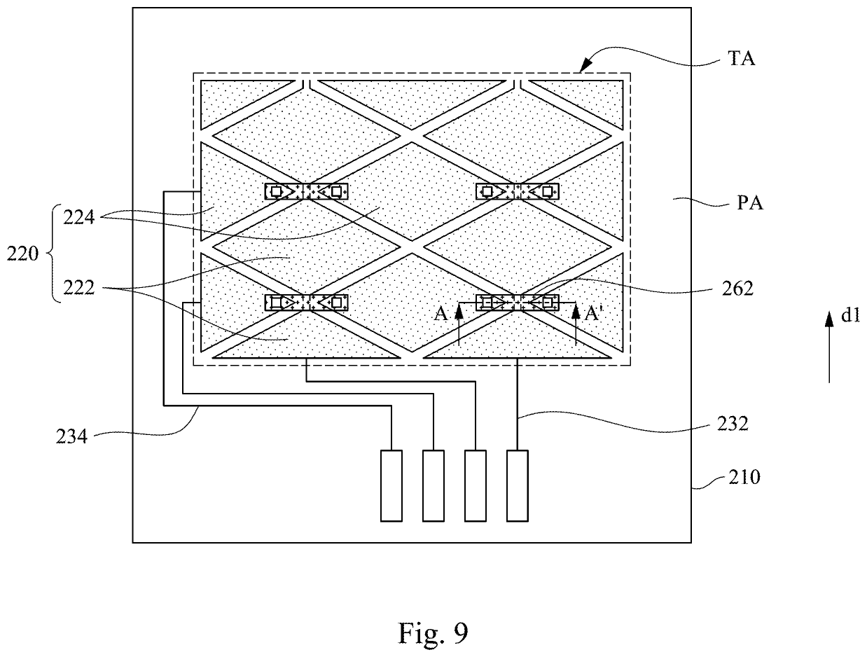

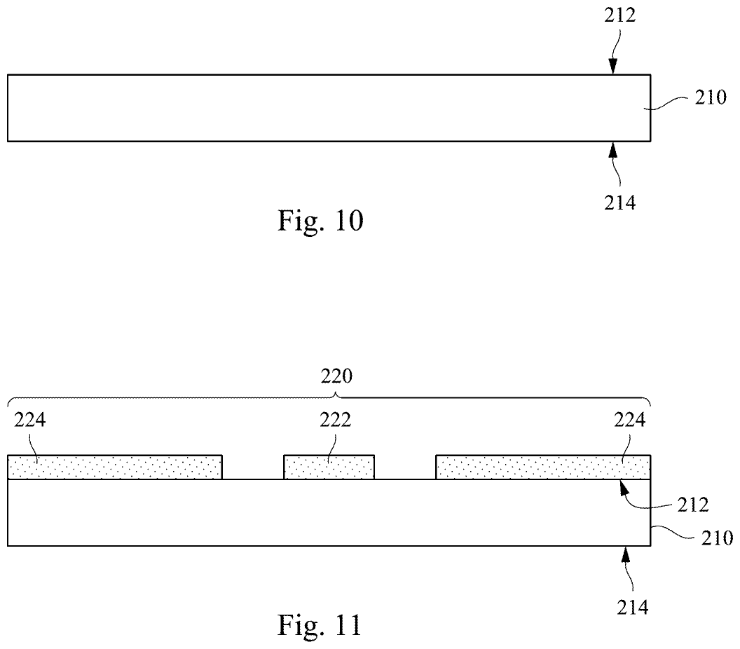

Another aspect of the present invention provides a method of manufacturing a touch panel. FIG. 8 is a flow chart of a method of manufacturing the touch panel according to another embodiment of the present invention. FIG. 9 is a partially enlarged top view of the manufactured touch panel. FIG. 10 to FIG. 15 are schematic cross-sectional views of various process stages along line A-A′ in FIG. 9. As shown in FIG. 8, a method 20 including step S21, step S22, step S23, step S24 and step S25 is provided.

At step S21, a transparent substrate 210 is provided, as shown in FIG. 9 and FIG. 10. The transparent substrate 210 has a first surface 212 and a second surface 214 opposite thereto. In an embodiment, the transparent substrate 210 comprises a touch sensing area “TA” and a peripheral line area “PA.” The peripheral line area “PA” surrounds the touch sensing area “TA.” In an embodiment, the transparent substrate 210 may comprise glass, sapphire, transparent resin or transparent ceramic, but is not limited thereto. In an embodiment, the transparent resin may comprise polyethylene terephthalate (PET), cycloolefin polymer (COP), polyimide (PI), polyethylene naphthalate (PEN), polycarbonate (PC) or other flexible plastic material. In other embodiments, the transparent substrate 210 is not limited to be a single layer. For example, a transparent protective film can be formed under the transparent substrate 210.

At step S22, a patterned transparent sensing layer 220 is formed on the first surface 212, as shown in FIG. 9 and FIG. 11. The patterned transparent sensing layer 220 is located in the touch sensing area TA on the transparent substrate 210. In various embodiments, the patterned transparent sensing layer 220 comprises a plurality of first sensing units 222 and a plurality of second sensing units 224.

In an example, the first sensing unit 222 and the second sensing unit 224 are composed of a transparent conductive material. In an example, the transparent conductive material comprises indium tin oxide, indium zinc oxide, aluminum oxide tin, aluminum zinc oxide, indium zinc oxide, other suitable oxides, or a stacked layer having at least two of the abovementioned materials.

In some embodiments, the first sensing unit 222 and the second sensing unit 224 are located on the same plane and are formed by the same lithographic process. The first sensing units 222 are arranged in a row in the first direction “d1”, and the second sensing units 224 are arranged in a column in a direction substantially perpendicular to the first direction “d1.” The two adjacent first sensing units 222 located in the same row are electrically connected to each other, and any adjacent ones of the second sensing units 224 located in the same row are electrically insulated from each other. In an embodiment, the top view pattern of the first sensing unit 222 and the second sensing unit 224 may be rectangular, rhombic, circular, elliptical, polygonal or irregular, but is not limited thereto.

As shown in FIG. 9, in various embodiments, the first peripheral line 232 and the second peripheral line 234 may be formed before, during, or after step S22. The first peripheral line 232 is electrically connected to the first sensing unit 222, while the second peripheral line 234 is electrically connected to the second sensing unit 224. In an embodiment, the first peripheral line 232 and the second peripheral line 234 may comprise a metal conductor or a transparent conductive material. In an embodiment, the metal conductor comprises copper, nickel, aluminum, silver, gold or other suitable conductors, and the transparent conductive material comprises indium tin oxide, indium zinc oxide, aluminum tin oxide, aluminum zinc oxide, indium germanium zinc oxide or other suitable oxides. In the present embodiment, the patterned transparent sensing layer 220 is formed simultaneously with the peripheral lines 232 and 234. In an embodiment, a layer of conductive material having a double layer of conductive material may be formed by two lithographic and two etching processes.

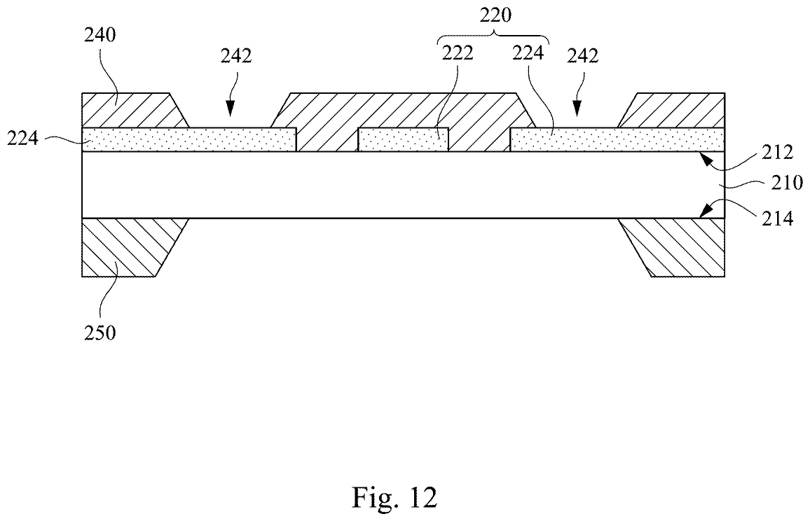

At step S23, a patterned first photoresist layer 240 is formed on the patterned transparent sensing layer 220, while a patterned second photoresist layer 250 is formed on the second surface 214, as shown in FIG. 12. In an embodiment, the first photoresist layer 240 after patterning has a plurality of openings 242 exposing a portion of the second sensing unit 224.

In an embodiment, a first photoresist layer covering the patterned transparent sensing layer 220 and a second photoresist layer covering the second surface 214 are formed. The first photoresist layer and the second photoresist layer are exposed and developed by using a first predetermined mask pattern and a second predetermined mask pattern respectively. In an embodiment, the first photoresist layer and the second photoresist layer may be patterned simultaneously or separately. In an embodiment, the first photoresist layer 240 and the second photoresist layer 250 comprise a negative photoresist material.

After performing step S23, the patterned first photoresist layer 240 and the patterned second photoresist layer 250 are treated with a curing process. In an embodiment, the curing process may include ultraviolet light irradiation, baking, or other suitable processes. The patterned first photoresist layer 240 may serve as an insulating layer during the subsequent formation of a conductive bridge to avoid short circuit between the first sensing unit 222 and the second sensing unit 224.

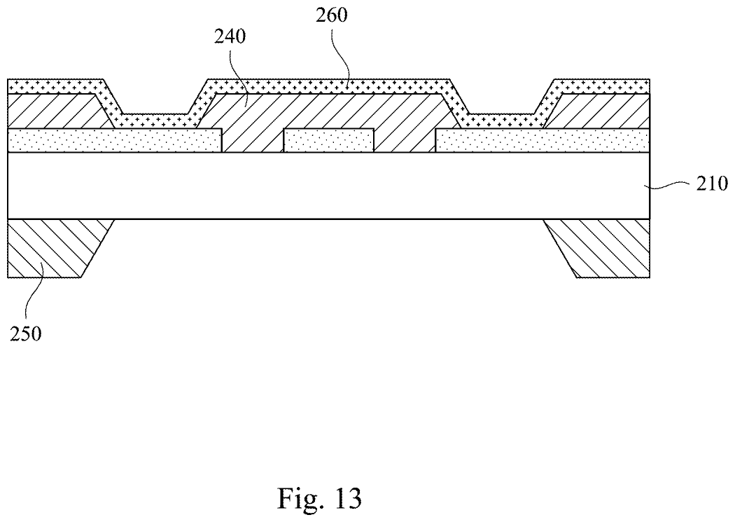

At step S24, a transparent conductive layer 260 covering the patterned first photoresist layer 240 is formed, as shown in FIG. 13. In an example, the transparent conductive layer 260 is conformally formed on the patterned first photoresist layer 240 by sputtering, evaporation, sol-gel, spray, pulsed laser deposition (PLD), chemical vapor deposition (CVD) or other suitable processes. In an example, the transparent conductive layer 260 may comprise a transparent conductive material. In an example, the transparent conductive material comprises indium tin oxide, indium zinc oxide, aluminum oxide tin, aluminum zinc oxide, indium zinc oxide, other suitable oxides or a stacked layer of at least two of the foregoing.

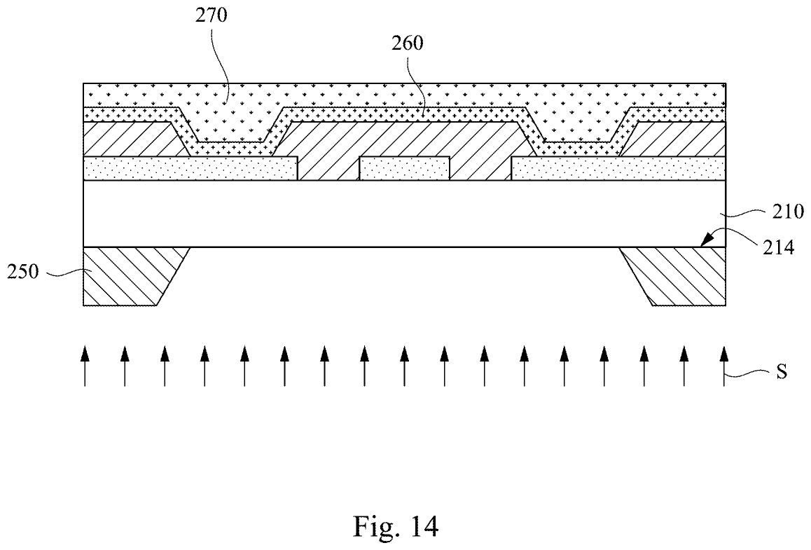

At step S25, the transparent conductive layer 260 is patterned to form a patterned conductive bridge 262 by using the patterned second photoresist layer 250 as a mask. As shown in FIG. 14, a third photoresist 270 is firstly formed on the transparent conductive layer 260. Since the patterned second photoresist layer 250 is located under the second surface 214 of the transparent substrate 210, an exposure light source “S” may be disposed under the patterned second photoresist layer 250. By using the patterned second photoresist layer 250 as a mask, a lithographic process is performed on the third photoresist 270, and the transparent conductive layer 260 is etched according to the pattern of the patterned third photoresist 270.

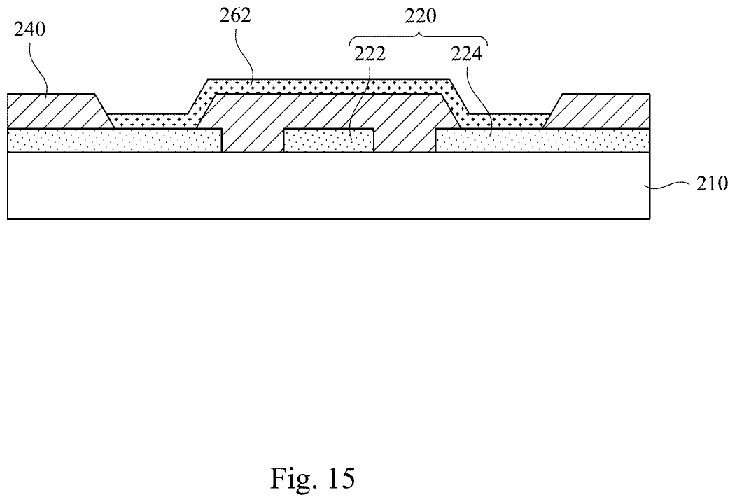

As shown in FIG. 15, after the transparent conductive layer 260 is etched, the third photoresist 270 and the patterned second photoresist layer 250 are removed to accomplish step S25. Since the patterned second photoresist layer 250 has been accomplished in step S23, there is no need for an additional mask or realignment in step S25. This embodiment can increase the bonding precision between the opening 242 of the patterned first photoresist layer 240 and the patterned conductive bridge 262.

In an embodiment, when the total thickness of the transparent substrate 210, the patterned transparent sensing layer 220, the patterned first photoresist layer 240 and the transparent conductive layer 260 is greater than a certain value, the optical density (OD) of the patterned second photoresist layer 250 needs to be greater than or equal to 3 (for example, 3.05, 3.1, 3.15, 3.2, 3.25, 3.3, 3.35, 3.4, 3.45, or 3.5), or the patterned second photoresist 250 needs to contain an opaque material. In this way, the light blocking performance of the patterned second photoresist 250 can be increased.

Reference is made to FIG. 9 and FIG. 15. The patterned conductive bridge 262 is used to electrically connect any adjacent ones of the second sensing units 224 located in the same column. The patterned conductive bridge 262 is electrically insulated from the first sensing unit 222 by the patterned first photoresist layer 240 underneath, thereby avoiding the signal interference between the first sensing unit 222 and the second sensing unit 224. In various embodiments, the top view pattern of the patterned conductive bridge 262 may be rectangular, dumbbell-shaped, elliptical or the like, but is not limited thereto.

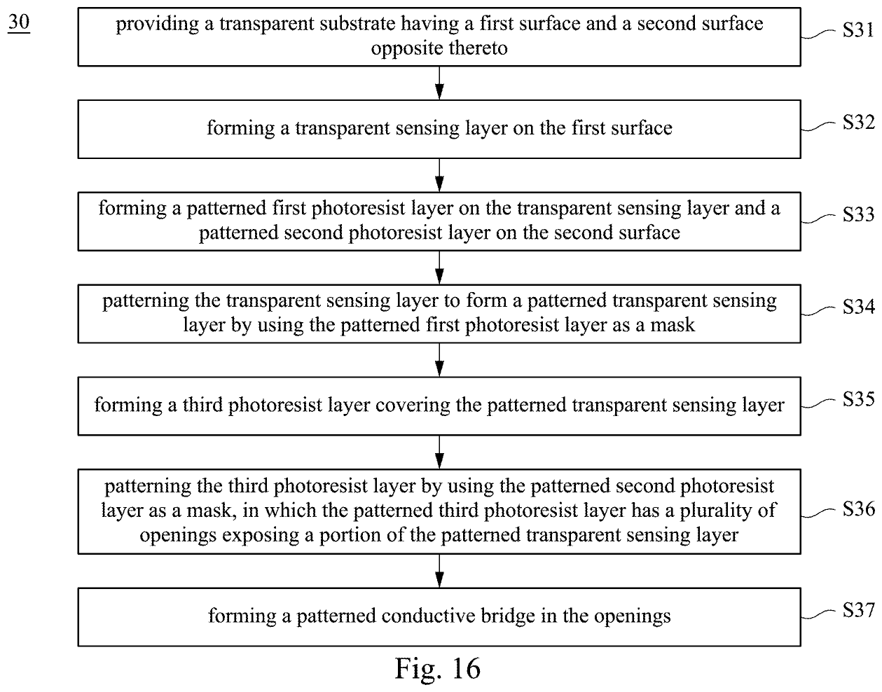

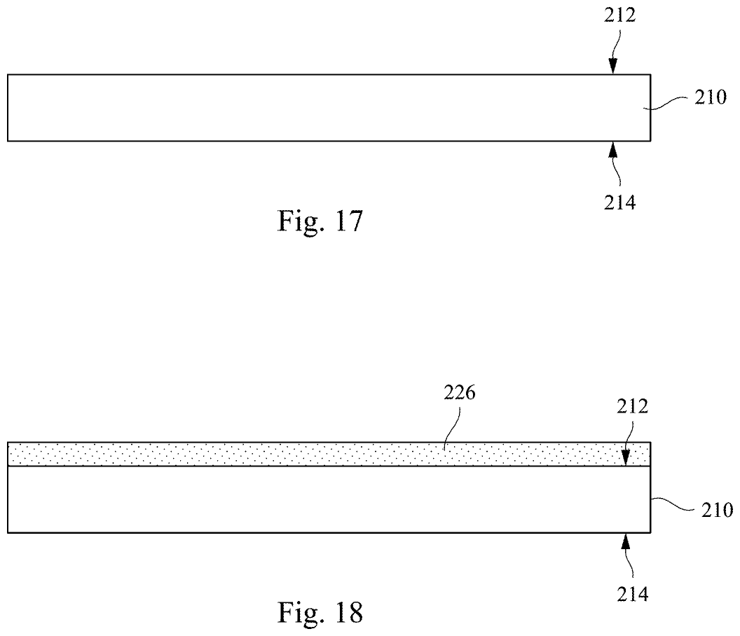

Another aspect of the present invention provides a method of manufacturing a touch panel. FIG. 16 is a flow chart of a method of manufacturing a touch panel according to another embodiment of the present invention. FIG. 17 to FIG. 23 are schematic cross-sectional views of various process stages in the method of manufacturing the touch panel of the present invention, and the cross-sectional positions thereof are the same as those in FIG. 10 to FIG. 15. As shown in FIG. 16, a method 30 including step S31, step S32, step S33, step S34, step S35, step S36 and step S37 is provided. The same components are denoted by the same reference numerals in the following embodiments for simplicity. The following description may mainly describe the differences between each embodiment without providing details of the repeating context.

At step S31, a transparent substrate 210 is provided, as shown in FIG. 17. The transparent substrate 210 has a first surface 212 and a second surface 214 opposite thereto. The material and other features of the transparent substrate 210 may be the same as or similar to the transparent substrate 210 described above with respect to FIG. 10, and details are not repeated herein.

At step S32, a transparent sensing layer 226 is formed on the first surface 212, as shown in FIG. 18. The material, the manufacturing method and other features of the transparent sensing layer 226 may be the same as or similar to the patterned transparent sensing layer 220 described above with respect to FIG. 11, and therefore details are not repeated herein.

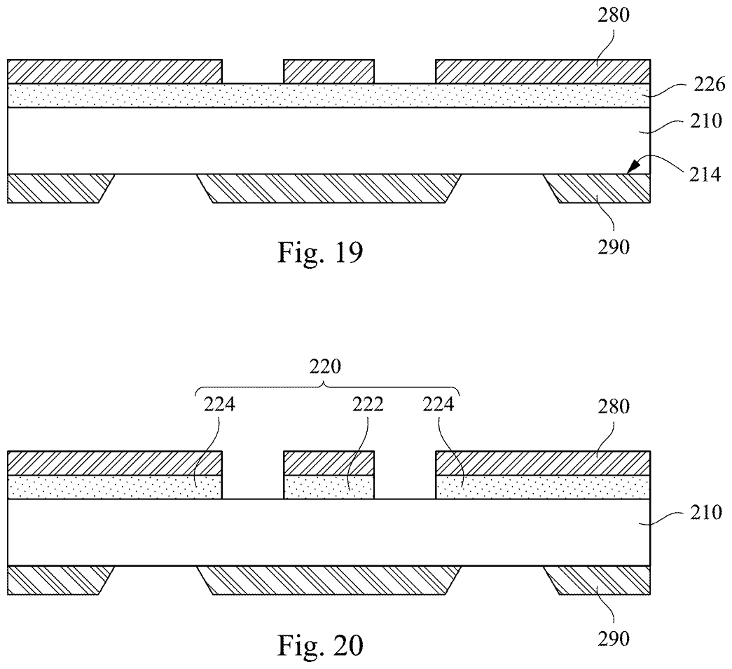

At step S33, a patterned first photoresist layer 280 is formed on the transparent sensing layer 226 and a patterned second photoresist layer 290 is formed on the second surface 214, as shown in FIG. 19. The material, fabrication method and other features relating to the patterned first photoresist layer 280 and the patterned second photoresist layer 290 may be the same as or similar to those of the patterned first photoresist layer 240 and the patterned second photoresist layer 250 described above with respect to FIG. 12, and therefore details are not repeated herein. In various embodiments, after performing step S33, the patterned first photoresist layer 280 and the patterned second photoresist layer 290 are cured by ultraviolet light irradiation or baking, or treated with other suitable curing processes.

At step S34, the transparent sensing layer 226 is patterned by using the patterned first photoresist layer 280 as a mask, as shown in FIG. 20. In an embodiment, this step can be accomplished by an etching process. Since the patterned second photoresist layer 290 has been treated with a curing process, it is not eroded by the etching solution. In various embodiments, after the step S34 is completed, the patterned first photoresist layer 280 can be removed by a stripping process, but the patterned second photoresist layer 290 is not removed. A patterned transparent sensing layer 220 is formed after the patterning of the transparent sensing layer 226 and comprises a plurality of first sensing units 222 and a plurality of second sensing units 224. In some embodiments, the first sensing unit 222 and the second sensing unit 224 are located on the same plane. For a detailed description of the first sensing unit 222 and the second sensing unit 224, reference may be made to the foregoing and therefore are not repeated herein.

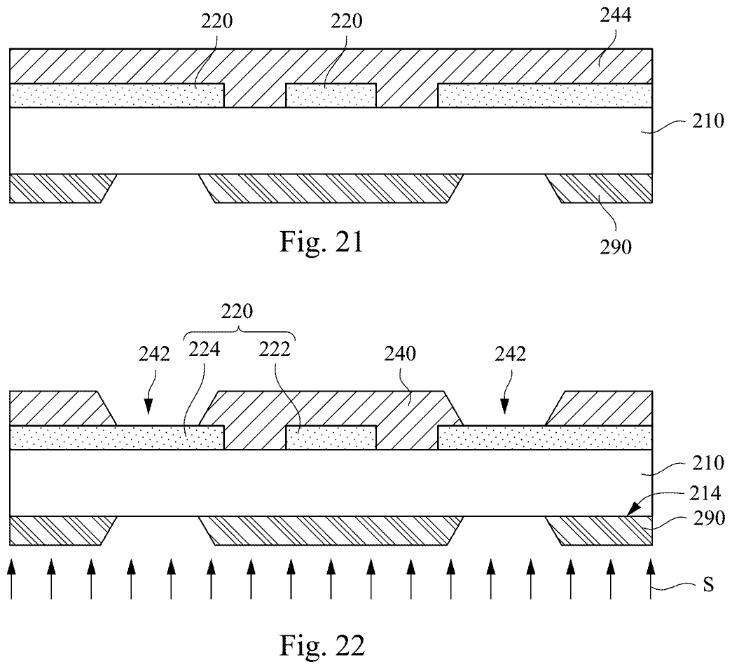

At step S35, a third photoresist layer 244 is formed covering the patterned transparent sensing layer 220, as shown in FIG. 21. In an embodiment, the third photoresist layer 244 comprises a negative photoresist material. In an embodiment, the third photoresist layer 244 may be formed by a suitable method such as spin coating, screen printing, spray coating, or the like.

At step S36, the third photoresist layer 244 is patterned by using the patterned second photoresist layer 290 as a mask. The patterned third photoresist layer 240 has a plurality of openings 242 exposing a portion of the patterned transparent sensing layer 220, as shown in FIG. 22. Since the patterned second photoresist layer 290 is located under the second surface 214 of the transparent substrate 210, the exposure light source “S” may be disposed under the patterned second photoresist layer 290, and the patterned second photoresist layer 290 may serve as a mask during a lithographic process performed on the third photoresist layer 244. The patterned second photoresist layer 290 is removed to accomplish step S36.

After performing step S36, the patterned third photoresist layer 240 is treated with a curing process. In an embodiment, the curing process may include ultraviolet light irradiation, baking, or other suitable processes. The patterned third photoresist layer 240 may serve as an insulating layer during the subsequent formation of a conductive bridge to avoid short circuit between the first sensing unit 222 and the second sensing unit 224. Since the patterned second photoresist layer 290 has been accomplished in step S33, there is no need for an additional mask or realignment in step S36. In addition, the present embodiment can reduce the alignment error between the transparent sensing layer 220 after patterning and the opening 242 of the third photoresist layer 240 after patterning.

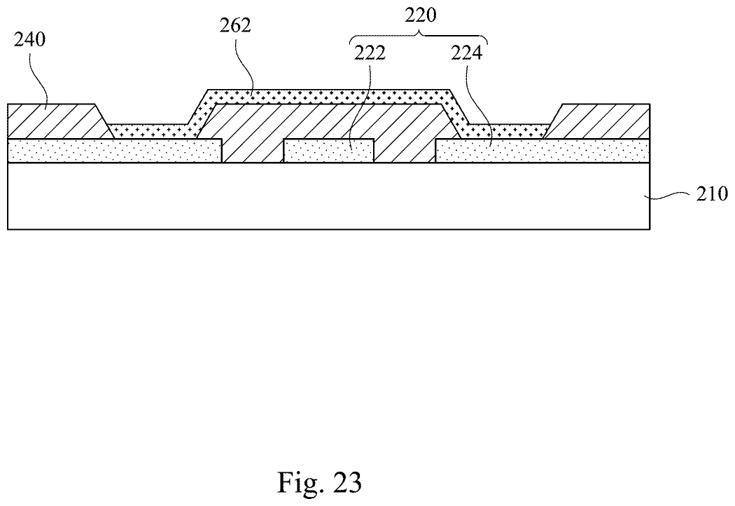

At step S37, a patterned conductive bridge 262 is formed in the opening, as shown in FIG. 23. The patterned conductive bridge 262 is used to electrically connect any adjacent ones of the second sensing units 224 located in the same column. The patterned conductive bridge 262 is electrically insulated from the first sensing unit 222 by the patterned first photoresist layer 240 underneath, thereby avoiding the signal interference between the first sensing unit 222 and the second sensing unit 224. Reference is now made to FIG. 8. In an embodiment, the top view pattern of the patterned conductive bridge 262 may be rectangular, dumbbell-shaped, elliptical or the like, but is not limited thereto.

In summary, the method for manufacturing a touch panel provided by the present invention applies the means of double-sided patterning described above, thereby reducing the cumulative alignment error among multiple lithographic processes. In addition, the electrical connectivity between the second sensing units is increased, resulting in high production yield of touch panel.

While the invention has been described above by embodiments, it is not intended to limit the invention, and the disclosure may be altered and modified without departing from the spirit and scope of the invention. Therefore, the scope of protection of the disclosure is determined by the scope of the appended claims.

What is claimed is:

1. A double-sided patterning method, comprising steps of:
providing a transparent laminate having a first surface and a second surface opposite thereto;
forming a patterned first photoresist layer and a patterned second photoresist layer respectively on the first surface and the second surface;
forming a transparent layer covering the patterned first photoresist layer; and
patterning the transparent layer by using the patterned second photoresist layer as a mask.

2. The method according to claim 1, wherein the step of forming the patterned first photoresist layer and the patterned second photoresist layer respectively on the first surface and the second surface comprises selecting the patterned second photoresist layer to have an optical density of greater than or equal to 3, or selecting the patterned second photoresist layer to comprise an opaque material.

3. A method for manufacturing a touch panel, comprising:
providing a transparent substrate having a first surface and a second surface opposite thereto;
forming a patterned transparent sensing layer on the first surface;
forming a patterned first photoresist layer and a patterned second photoresist layer respectively on the patterned transparent sensing layer and the second surface;
forming a transparent conductive layer covering the patterned first photoresist layer; and
patterning the transparent conductive layer by using the patterned second photoresist layer as a mask to form a patterned conductive bridge.

4. The manufacturing method according to claim 3, wherein the step of forming the patterned transparent sensing layer on the first surface comprises forming a plurality of first sensing units and a plurality of second sensing units on the first surface, wherein the first sensing units are arranged in a row in a first direction, and the second sensing units are arranged in a column in a direction substantially perpendicular to the first direction.

5. The manufacturing method according to claim 4, wherein the step of forming the patterned first photoresist layer and the patterned second photoresist layer respectively on the patterned transparent sensing layer and the second surface comprises:
forming a plurality of openings in the patterned first photoresist layer, each openings exposing a portion of each second sensing units.

6. The manufacturing method according to claim 4, wherein the step of patterning the transparent conductive layer by using the patterned second photoresist layer as the mask to form the patterned conductive bridge comprises:
electrically connecting the patterned conductive bridge to any adjacent ones of the second sensing units.

7. The manufacturing method according to claim 3, wherein the step of forming a patterned first photoresist layer and a patterned second photoresist layer respectively on the patterned transparent sensing layer and the second surface comprises selecting the patterned second photoresist layer to have an optical density of greater than or equal to 3, or selecting the patterned second photoresist layer to comprise an opaque material

8. A method of manufacturing a touch panel, comprising:
providing a transparent substrate having a first surface and a second surface opposite thereto;
forming a transparent sensing layer on the first surface;
forming a patterned first photoresist layer and a patterned second photoresist layer respectively on the transparent sensing layer on the second surface;
patterning the transparent sensing layer by using the patterned first photoresist layer as a mask to form a patterned transparent sensing layer;
forming a third photoresist layer covering the patterned transparent sensing layer;
patterning the third photoresist layer by using the patterned second photoresist layer as a mask, wherein the patterned third photoresist layer has a plurality of openings exposing a portion of the patterned transparent sensing layer; and
forming a patterned conductive bridge in the openings.

9. The manufacturing method according to claim 8, wherein the step of forming the patterned transparent sensing layer on the first surface comprises forming a plurality of first sensing units and a plurality of second sensing units on the first surface, wherein the first sensing units are arranged in a row in a first direction, and the second sensing units are arranged in a column in a direction substantially perpendicular to the first direction.

10. The manufacturing method according to claim 9, wherein the step of forming the patterned conductive bridge in the openings comprises:
electrically connecting the patterned conductive bridge to any adjacent ones of the second sensing units.
